(19) United States
(12) Patent Application Publication
(10) Pub. No.: US 2025/0322123 A1
(43) Pub. Date: Oct. 16, 2025

(54) END OF PROJECT PREDICTION

(71) Applicant: Level Capital, LLC, Kirkland, WA (US)

(72) Inventor: Terry Joseph Songy, JR., Ponchatoula, LA (US)

(21) Appl. No.: 19/175,938

(22) Filed: Apr. 10, 2025

Related U.S. Application Data
(60) Provisional application No. 63/632,985, filed on Apr. 11, 2024.

(51) Int. Cl. G06F 30/27; G06F 30/13

(52) U.S. Cl. CPC G06F 30/27; G06F 30/13

(57) ABSTRACT

Apparatuses, systems, and techniques to predict a time to perform a task. In at least one embodiment, a method comprises generating a model to predict an amount of time to perform one or more first tasks and predicting, using the model, the time to perform the one or more first tasks based at least on information indicating progress of the one or more first tasks and information indicating progress of one or more second tasks.

### CLAIM OF PRIORITY

This application claims the benefit of U.S. Provisional Application No. 63/632,985 titled “END OF PROJECT PREDICTION,” filed Apr. 11, 2024, the entire contents of which is incorporated herein by reference.

### FIELD OF THE INVENTION

At least one embodiment pertains to techniques to predict completion of a project according to various novel techniques.

### BACKGROUND

A project (e.g., a construction project) can be modelled as a time-bound, or static, system in that it has defined start and end points. However, a more realistic model must represent the project as an open system because it interacts with and is influenced by its external environment, and the information available within that system is non-continuous. Techniques for predicting project completion can be improved.

### BRIEF DESCRIPTION OF DRAWINGS

FIG. 1 illustrates a framework to perform end of project prediction, according to at least one embodiment;

FIGS. 2A and 2B illustrate an example physics-informed environment, according to at least one embodiment;

FIG. 3 illustrates an example of end of project prediction, according to at least one embodiment;

FIG. 4 illustrates a flow diagram of a process of performing end of project prediction, according to at least one embodiment; and

FIG. 5 illustrates a flow diagram of a process of generating TVCs, according to at least one embodiment.

### DETAILED DESCRIPTION

A physics-informed environment can be created around a system modelling a project to more efficiently extrapolate the information needed to run predictions within the system. Three phases may be involved in generating a prediction. For example, two phases that create and populate the environment (environmental phases) and a final phase for prediction.

The environmental phases may include—1) a Creation Phase where the environment is created and segmented into 10 equal longitudinal sections (e.g., with topographical variance) that correspond to the percent complete of the project and 2) a Population Phase in which each longitudinal section's topographical variability is achieved through feature engineering and analysis of gradient boosting and convolution neural network model outputs to comprehend the algorithmic underpinnings and achieve insight into the operational mechanics. In the Prediction Phase, in at least one embodiment, new data may be measured as it moves through each section of the environment and, depending on the movement through a particular section, a prediction may be generated based on algorithms created during the population phase.

In at least one embodiment, a method, apparatus, and/or non-transitory computer-readable medium storing instructions to cause a processor(s) to perform instructions, are to generate a model to predict an amount of time to perform one or more first tasks (e.g., a project, such as the project discussed above), and predict, using the model, the time to perform the one or more first tasks based, at least in part, on information (e.g., associated with the physics-informed environment, discussed above) indicating progress of the one or more first tasks and information indicating progress of one or more second tasks (e.g., other projects). The task(s) may comprise a construction project. The model may be generated such that an effect on the prediction of the information indicating progress of the one or more first tasks is substantially proportional to a difference between the information indicating progress of the one or more first tasks and the information indicating progress of the one or more second tasks. The information indicating progress of the one or more first tasks may comprise one or more values determined based, at least in part, on one or more values indicating a progress of the task compared to an elapsed time corresponding to the one or more first tasks. One or more temporal checkpoints (e.g., construction loan draw dates) may be assigned to the task and the information indicating progress of the one or more first tasks comprises one or more values determined based, at least in part, on one or more values indicating a progress of the task following a previous checkpoint, and/or multiple previous checkpoints. The information indicating progress of tasks may include at least two values (e.g., “speed,” “distance,” and/or “velocity” as discussed below) and weightings assigned to these values may be generated by one or more neural networks.

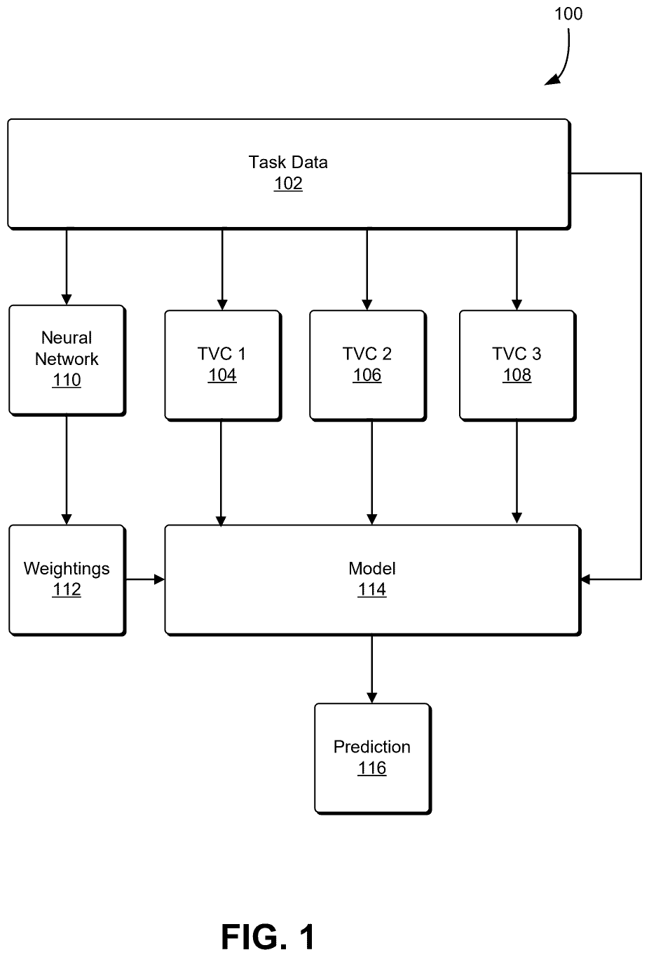

FIG. 1 illustrates a framework 100 to perform end of project prediction, according to at least one embodiment. Framework 100 may be implemented by one or more processors (e.g., CPUs and/or GPUs), storage devices such as hard drives, memory such as RAM, any other suitable hardware, any suitable software, and/or any other suitable combination hardware and software. Framework 100 includes task data 102, temporal variability calculations (TVCs) 1-3 104, 106, and 108, a neural network 110, weightings 112, a model 114, and a prediction 116. Framework 100 may also include additional components, not shown, as necessary, and/or one or more duplicates of any of components 102-116.

Task data 102 includes information regarding performance of a task. An example of a task is a construction project. Continuing with the example of a construction project, task data 102 may include, for example, a start date, a scheduled end date, one or more inspection dates, one or more loan draw dates, one or more values indicating progress (for example, expressed as a percentage of completion) of the project at various dates, and/or any other suitable information. Task data 102 may include data about one task, or multiple tasks.

In at least one embodiment, TVCs 104, 106, and 108 comprise different values calculated based on task data 102. TVC 104 (which may be referred to as “distance”) comprises, for example, a measure of progress over the total time associated with a task. For example, TVC 104 may be expressed in terms of percentage completion per day. Continuing with the example of a construction project, distance may be calculated by measuring the time (e.g., in days) the current draw (tₙ) is from to (initial time, such as 30 days prior to the first draw event) and then dividing the percent complete (p) by that value, in other words pₙ/(tₙ−tₒ).

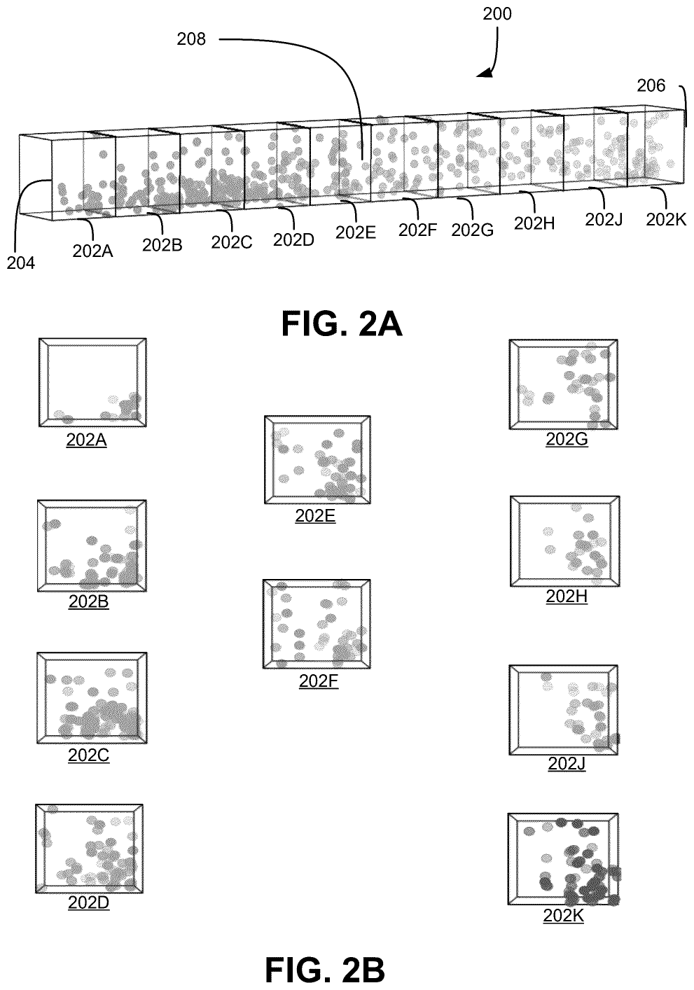

In at least one embodiment, distance represents the cumulative effects of reductionism in the environment. Each longitudinal section's (discussed with reference to FIG. 2) topography is influenced by the immediately preceding section, which in turn is shaped by its own preceding section, and so on. Therefore, distance has a direct relationship with the immediately preceding section and a diminishing indirect relationship with each prior section. This measure provides a general indication of movement through the environment and is the least sensitive of the three TVCs.

TVC 106 (which may be referred to as “speed”) comprises, for example, a measure of progress over a time since a last checkpoint associated with a task. A checkpoint may be any suitable point in time, such as a loan draw date or a time at which a certain percentage of completion is reached. Continuing with the example of a construction project, speed may be considered a measure of movement between draw events and gives a recent indication of movement and as such may be a more sensitive calculation, given by: pₙ/(tₙ−tₙ₋₁). Calculation of speed (TVC 106) may be omitted if no checkpoint has been reached (e.g., tₙ₋₁ does not yet exist), or, in such a situation, speed and distance can be the same.

In at least one embodiment, speed measures movement between draw events and contrasts with distance in that it provides only a recent indication of movement (e.g., days since prior draw and completion percentage). It is the most sensitive of the three variables, as each section's topography is entirely unaffected by preceding sections. Herein lies an incorporation of chaos theory: small changes within the system can dramatically affect the topography within the environment, whether considering individual sections or the environment as a whole. Of the three discussed TVCs, there may be the least amount of similarity between sections.

TVC 108 (which may be referred to as “velocity”) comprises, for example, a value based on (e.g., an average) a previous number (e.g., the last three) speed values. In at least one embodiment, velocity is the measure of the three most recent speed(s) calculations (can be less than three if three draw events have not yet occurred). This creates the balance between distance and speed and the marriage of reductionism and chaos. The individual sections may have more similarity to adjacent sections than that of speed, but less than distance. Velocity may be calculated by, for example, ((sₙ)+(sₙ₋₁)+(sₙ₋₂))/3, where s indicates a speed.

As used herein, the terms “distance,” “speed,” and “velocity” are associated with TVCs 104, 106, and 108, respectively, and do not necessarily have their conventional physical meanings. In at least one embodiment, other terms are chosen to represent TVCs 104, 106, and 108. In at least one embodiment, one, two, or greater than three TVCs are used. In at least one embodiment, TVCs are calculated in a manner different than that which is described above.

Neural network 110 may be any suitable neural network to generate weightings 112 (discussed in greater detail below) to be used by model 114. Neural network 110 may generate weightings 112 based on previously collected data (e.g., of completed projects) included in task data 102. Neural network 110 may be any suitable neural network, such as a convolutional neural network, trained based, at least in part, on TVCs 104, 106, and 108 and completion times of completed projects. In at least one embodiment, neural network 110 is multiple neural networks.

In at least one embodiment, topographical variability calculations normalize and weight the distance (d), speed (s), and velocity (v) variables using a coefficient of variation (CV). That process may, for example, output weighting mechanisms for each of the sections is as follows:

dᵢ=1/CV_{d}

sᵢ=1/CVₛ

vᵢ=1/CVᵥ

TᵢC=dᵢ+sᵢ+vᵢ

Wdᵢ=dᵢ/TᵢC

Wsᵢ=sᵢ/TᵢC

Wvᵢ=vᵢ/TᵢC

In at least one embodiment, gradient boosting and/or convolutional models are be created, trained, tuned, and analyzed to get a sense of the operational mechanics, as stated above. In at least one embodiment, these models were output within a certain timeframe, e.g., number of days, for each of the sections with little influence from the other features. This may indicate, for example a strong relationship between percent complete and time remaining. In at least one embodiment, to reduce breadth of this output, a dataframe using only projects considered to be typical (based on the majority groups and data distribution in the original set) may be run though the models to still favor static timeframes but with a reduction in volatility. In at least one embodiment, those values and ranges a assigned to the corresponding longitudinal section as three new columns, expected end of construction (EOC) and the expected EOC range expressed as Expected EOC Upper Bound and Expected EOC Lower Bound. This creates the macro system that represents the general expected movement through the environment (TVCs measured in each longitudinal section). In other words, at any given point, if a project were to perform like other like and kind projects, it would be completed within n number of days with an error range.

In at least one embodiment, neural network 110 is omitted from framework 100, and instead previously and/or manually generated (or otherwise suitably generated) weightings 112 are used by model 114.

Model 114 comprises a mathematical model and/or algorithm to generate a prediction 116 (e.g., a time for completion of a task) based on TVCs 104, 106, 108, weightings 112, and/or task data 102. Model 114 may also use any other suitable information to generate prediction 116.

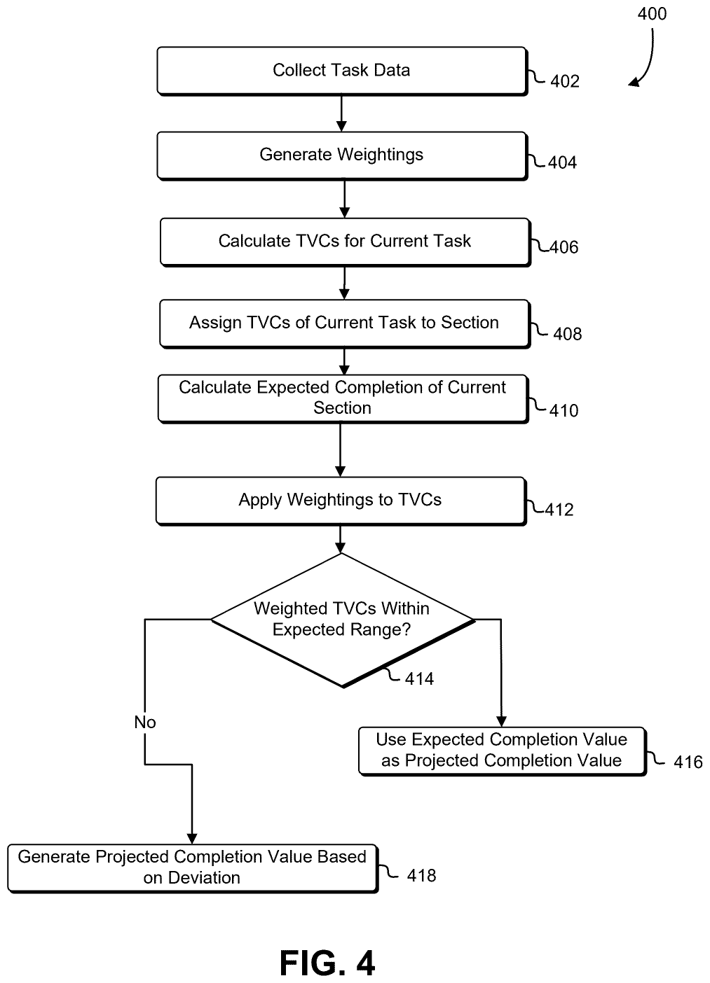

In at least one embodiment, performing model 114 comprises performing a number of steps (e.g., as discussed in greater detail with reference to FIG. 4). For example, the current task can be mapped to a longitudinal section (e.g., as discussed with reference to FIG. 2) based on a degree of completion (e.g., a percentage). Within that section, an expected completion time (e.g., an EOC as discussed above) may be considered a default value. This expected completion time may be hard coded based on historical data. Different sections may have different expected completion times. Performing model 114 may further comprise applying the weightings 112 to the TVCs 104-108 (e.g., distance, speed, and velocity), and/or combining these values to produce a weighted sum. If the weighted sum is within a tolerance for the current section, the expected completion time may be used as the prediction 116. The tolerance may be defined by, for example, expected upper and lower values determined from historical data and/or generated by neural network 110. If the weighted sum is not within the tolerance, model 114 may further comprise generating prediction 116 including any of a lower projection by multiplying the weighted sum by a lower typical time to completion value, an upper projection by multiplying the weighted sum by an upper typical time to completion value, a projected time remaining by taking the average of the lower and upper projections, and/or a projected completion date by adding the projected time remaining to the current date (or another suitable date, such as a most recent draw date).

Use of the TVCs (e.g., the TVCs 104-108) and other elements illustrated in FIG. 1 overcomes problems associated with using a neural network alone to make prediction 116. For example, a neural network trained to make prediction 116 based on task data 102 may suffer from multiple problems such as overfitting (e.g., due to a lack of training data and/or a failure to account for the context of specific data). On the other hand, a neural network (e.g., neural network 110) is well suited to tasks such as generating weightings 112, e.g., based on general patterns of how much particular TVCs affect completion times. Once the weightings 112 are generated, the weightings 112 can be applied to TVCs that are specific to a task and/or associated contextual information to make a reliable prediction, even if a similar task and/or contextual information was not included in data used to train neural network 110. This represents an improvement over a neural network alone, where predictions become unreliable when a situation (e.g., task data) falls outside the data used to train the neural network. The TVCs themselves also represent improvements over conventional techniques in that they simultaneously account for long term patterns (e.g., via distance) and recent changes in patterns (e.g., via speed and velocity). In addition, the techniques and devices described herein represent improvements in computer resource usage, compared to using a neural network to make prediction 116, because once weightings 112 are generated the use of the neural network 110 can be omitted (unless the weightings 112 are to be updated) from the process of making prediction 116.

FIGS. 2A and 2B illustrate an example physics-informed environment 200, according to at least one embodiment. FIG. 2A illustrates the environment 200, such that the horizontal axis represents time from start of project 204 to end of project 206 and the vertical axis represents TVC values (e.g., distance, speed, or velocity). The third axis may represent any suitable quantity (in the example of a construction project, the third axis may represent, for instance, loan value), or be omitted. Environment 200 may alternatively include four or more dimensions.

In the illustrated example of FIG. 2A, environment 200 is divided into ten sections (e.g., longitudinal sections as discussed with reference to FIG. 1) 202A-202K, such that the first section 202A corresponds to the beginning 204 of the task to 10% completion, the second section 202B corresponds to 10% to 20% completion, . . . , and the tenth section 202K corresponds to 90% completion to completion 206. In other examples, environment 200 may be divided into fewer or greater than ten sections and/or be divided into unequal sections. FIG. 2B illustrates the individual sections of the environment 202A-202K, viewed such that the time axis points into the diagram.

Environment 200 is populated with data points 208. Data points 208 may represent, for example distance, speed, and velocity (e.g., TVC 1 104, TVC 2 106, and TVC 3 108) of tasks at different stages of completion (e.g., within different sections 202A-202K). Different environments 200 may be respectively generated for distance, speed, and velocity data. Data points 208 may include distance, speed, and/or velocity information for a current task for which a prediction (e.g., prediction 116) is to be generated (e.g., via model 114), information for other tasks which have already been completed, information for other tasks occurring concurrently with the current task, information generated by a neural network (e.g., neural network 110), and/or any other suitable information.

In at least one embodiment, a model (e.g., model 114) includes mathematically modelling environment 200 as a physical environment where data points 208 cause interference and resonance patterns, based on their positions relative to other data points 208 and the edges of their respective sections 202A-202K. As illustrated in FIGS. 2A and 2B figures above, each longitudinal section 202A-202K possesses a distinct landscape. While adjacent sections may exhibit some similarity, there may be sufficient variance to warrant individual consideration rather than treating the entire environment as a homogeneous whole. This may be particularly important when incorporating the weighting of the TVCs (e.g., TVCs 104-108) into the environment 200. The environment may be characterized by divergence and convergence, changes in topographical density, resonance and interference, and elements of emergentism.

These elements may be integral to each of the TVCs and underscore the necessity of the environment's 200 structure. In at least one embodiment, a fully populated environment 200 is constantly altered by data moving through it. In at least one embodiment, TVCs capture and reflect spatial and temporal flux within the environment 200 due to the presence of exogenous variables (e.g., weather delays, material delays, logistical delays, etc.).

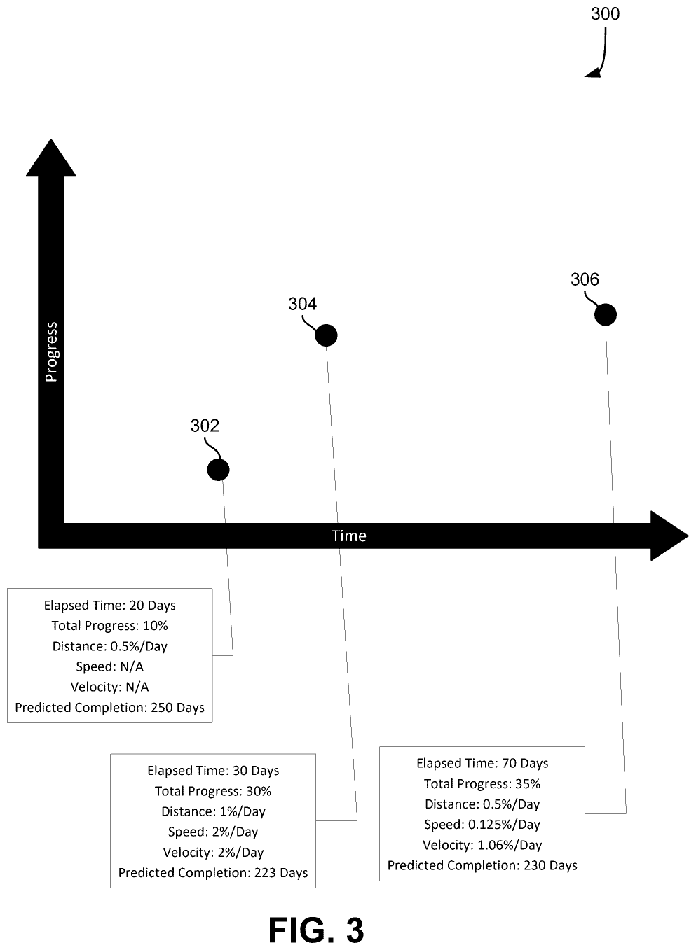

FIG. 3 illustrates an example 300 of end of project prediction, according to at least one embodiment. Example 300 is illustrated such that progress (e.g., corresponding to sections 202A-202K in FIG. 2) is on the vertical axis and time is on the horizontal axis. While example 300 is two-dimensional, other examples may include three or more dimensions, one dimension, and/or use any other suitable labels on the axes. Example 300 includes three data points 302, 304, and 306 corresponding to a task. Other examples may include fewer than or greater than three data points. Data points 302, 304, and 306 include an elapsed time and a total progress, as well as distance, speed, and velocity (e.g., TVCs 104-108), as well as a predicted completion (e.g., prediction 116). In the illustrated example of FIG. 3, data points 302, 304, and 306 correspond to temporal checkpoints (e.g., corresponding to loan draw dates). Other embodiments may include checkpoints at times different than data points. The values illustrated in FIG. 3 should be understood as examples only. Other examples may include a different number of checkpoints and/or datapoints, checkpoints and/or datapoints that occur on different days, datapoints with different values and/or different types of values, etc.

In the example data point 302, the elapsed time is 20 days (e.g., since the start of a project) and a total progress of 10%. Given these values, data point 302 has a distance of 0.5% per day. As illustrated, no speed has been calculated because no previous checkpoint exists. Similarly, no velocity has been calculated since no speed has been calculated. As illustrated, with a distance of 2% per day, at 10% completion, a model (e.g., model 114) has predicted that the task will be completed after an elapsed time of 250 days.

In the example data point 304, the elapsed time is 30 days (e.g., since the start of a project) and a total progress of 30%. Given these values, data point 304 has a distance that has increased to 1% per day. As illustrated, since ten days have passed since the checkpoint coinciding with data point 302, and the difference in progress between data points 302 and 304 is 20%, the speed of datapoint 304 is 2% per day. Since only one speed value has been calculated, the velocity of datapoint 304 is the same at 2% per day. As illustrated, with a distance of 1% per day, a speed of 2% per day, and a velocity of 2% per day, at 30% completion, a model (e.g., model 114) has predicted that the task will be completed after an elapsed time of 223 days.

In the example data point 306, the elapsed time is 70 days (e.g., since the start of a project) and a total progress of 35%. Given these values, data point 304 has a distance that has been reduced to 0.5% per day. As illustrated, since 40 days have passed since the previous checkpoint (corresponding to data point 304), and the difference in progress between data points 304 and 306 is 5%, the speed of datapoint 306 is 0.125% per day. Based on this speed and the speed of data point 304, the velocity of datapoint 306 is 1.0625% per day (shown rounded to 1.06%). As illustrated, with a distance of 0.5% per day, a speed of 0.125% per day, and a velocity of 1.06% per day, at 35% completion, a model (e.g., model 114) has predicted that the task will be completed after an elapsed time of 230 days. In the illustrated example, the increase in predicted elapsed time to completion between data points 304 and 306 is only seven days, which is disproportionately small compared to the reductions in distance, speed, and velocity. One possible reason for this is, for example, that such a slowdown might be expected, given historical data (for example, data point 306 might be mapped to the densely populated lower-right quadrant of section 202C shown in FIG. 2B), and/or similar performance has previously been associated with a later speed up. As discussed with reference to FIGS. 1 and 2, such factors may be accounted for by a model (e.g., model 114) when making a prediction (e.g., prediction 116).

FIG. 4 illustrates a flow diagram of a process 400 of performing end of project prediction, according to at least one embodiment. In at least one embodiment, process 400 implements, at least partially, performance of framework 100 illustrated in FIG. 1. Process 400 includes blocks 402-418. In some embodiments, blocks may be performed in an order other than what is illustrated in FIG. 4, one or more blocks may be omitted, and/or additional operations may be inserted before, after, in parallel with, and/or between the illustrated blocks.

At block 402, a processor or other suitable computing device collects task data (e.g., task data 102). As discussed at least with reference to FIGS. 1 and 2, the task data may include data corresponding to a current task or project, historical data corresponding to other tasks or projects, and/or any other suitable data to be used to generate TVCs to be used by a model (e.g., model 114) to make a prediction (e.g., prediction 116).

At block 404 a neural network (e.g., neural network 110) generates weightings (e.g., weightings 112). Block 404 may be omitted if the weightings have previously been generated. Weightings may also be determined by another suitable process, such as experimentally.

At block 406, a processor or other suitable computing device calculates TVCs (e.g., TVCs 104-108) for task data (e.g., from among task data 102) corresponding to a current task for which a prediction (e.g., prediction 116) is to be generated (e.g., via model 114). As discussed with reference to FIGS. 1-3, TVCs may include distance, speed, and velocity (as defined above with reference to FIG. 1). TVCs may also include any other suitable values based on task data and/or other information.

At block 408, a processor or other suitable computing device assigns the TVCs to a section (e.g., one of sections 202A-202K). As discussed above, this assignment may be based on a degree of completion of the task or project the TVCs are associated with. In other embodiments, this assignment may be based on any other suitable information.

At block 410, a processor or other suitable computing device calculates an expected completion time (e.g., an total number of days from start to finish) corresponding to the section to which the TVCs were assigned in block 408. As discussed above, this calculation may be based on historical data, neural-network-generated data, and/or any other suitable information. Block 408 may be omitted, for example, if the expected completion time for the current section had previously been calculated, such as when making a previous prediction.

At block 412, the weightings generated at block 404 are applied to the TVCs calculated at block 406. As discussed above, the weightings may be specific to the section to which the TVCs are assigned at block 408.

At block 414, a processor or other suitable computing device determines whether the weighted TVCs (or, for example, a sum of the weighted TVCs) from block 414 fall within an expected range, for example as discussed with reference with FIG. 1. In at least one embodiment, a TVC that falls within an expected range would be located within a densely populated portion of the section to which it is assigned (e.g., the lower-right portion of section 202A). If, at block 414, the TVCs fall within the expected range, the expected completion value from block 410 may be used as the projected completion value (e.g., corresponding to prediction 116) for the current project or task. If, at block 414, the TVCs to not fall within the expected range, at block 418 the processor or other suitable computing device generates the projected completion value based, at least in part, on the TVCs and the deviation between the TVCs and the expected range. This deviation may correspond to how physically distant the TVCs are from other TVCs within the same section. For example, a TVC located in the lower left quadrant of section 202E illustrated in FIG. 2B would have a large deviation from the expected range corresponding to that section. As discussed with reference at least to FIG. 1, generating this predicted completion may include calculating and taking the average of predicted upper and lower projections.

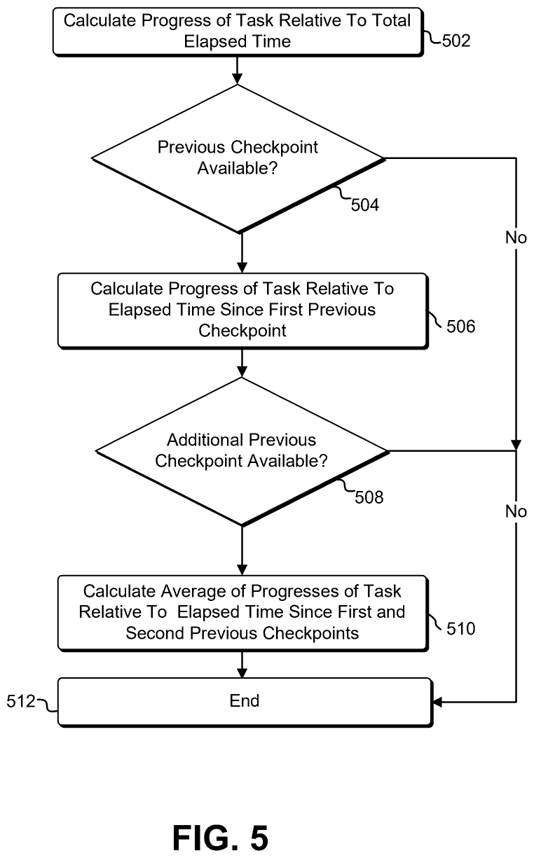

FIG. 5 illustrates a flow diagram of a process 500 of generating TVCs, according to at least one embodiment. In at least one embodiment, process 500 implements, at least partially, performance of framework 100 illustrated in FIG. 1, for example generating TVCs 104-108. Process 500 includes blocks 502-512. In some embodiments, blocks may be performed in an order other than what is illustrated in FIG. 5, one or more blocks may be omitted, and/or additional operations may be inserted before, after, in parallel with, and/or between the illustrated blocks. For example, while process 500 illustrates the generation of three TVCs (e.g., distance, speed, and velocity, as defined herein) according to the equations discussed at least with reference to FIG. 1, other embodiments may include the generation of fewer TVCs, additional TVCs, and/or TVCs according to other calculations.

At block 502, a processor or other suitable computing device calculate the progress (e.g., a percentage of completion) of a task or project relative to a total elapsed time. As discussed with reference to FIGS. 1-4, the quantity resulting from block 502 corresponds to the distance of the current task at the current time.

At block 504, the processor or other suitable computing device determines whether a previous checkpoint is available. If no previous checkpoint is available (e.g., the distance calculated at block 502 is the first distance calculated for the task, for example at a first draw date, as illustrated with respect to data point 302), process 500 concludes at block 512.

If, at block 504, a previous checkpoint is available (e.g., the distance calculated at block 502 corresponds to at least the second draw date), process 500 proceeds to block 506. At block 506, the processor or other suitable computing device calculates the progress of the task relative to an elapsed time since the previous checkpoint. As discussed with reference to FIGS. 1-4, the quantity resulting from block 506 corresponds to the speed of the current task at the current time.

At block 508, the processor or other suitable computing device determines whether another previous checkpoint is available. If no additional previous checkpoint is available (e.g., the speed calculated at block 506 is the first speed calculated for the task, for example at a second draw date), process 500 concludes at block 512. Alternatively, the quantity calculated at 506 can also be used as an output of block 510 (e.g., as illustrated in FIG. 3 with data point 304 having the same speed and velocity).

If, at block 508, an additional previous checkpoint is available (e.g., the speed calculated at block 506 corresponds to at least the third draw date), process 500 proceeds to block 510. At block 510, the processor or other suitable computing device calculates an average of progresses of the task or project relative to at least elapsed times since their respective previous checkpoints (e.g., an average of a current speed and at least one previous speed). In at least one embodiment, the quantity calculated at block 510 comprises an average of at most three such values (e.g., an average of at most three speeds). In at least one embodiment, block 510 uses a calculation other than an average (e.g., a geometric mean, a median, etc.). As discussed with reference to FIGS. 1-4, the quantity resulting from block 510 corresponds to the velocity of the current task at the current time.

In at least one embodiment, process 500 implements at least block 406 in FIG. 4.

The terms “a,” “an,” “the,” and similar references, when used to describe the disclosed embodiments (particularly in the claims), should be interpreted to encompass both singular and plural forms. Words like “comprising,” “having,” “including,” and “containing” are intended to be open-ended expressions, meaning, for example, “including but not limited to,” unless specified otherwise. The use of “may” or “can” is meant to provide examples without restricting any specific embodiment, component, or function described herein.

Conjunctive expressions, such as phrases like “at least one of A, B, and C” should generally be understood in context to mean that an item, term, or element can be A, B, C, or any nonempty combination of A, B, and C, unless explicitly stated otherwise. The term “plurality” means “multiple items” (e.g., “a plurality of items” indicates two or more items). The phrase “based on” should be interpreted as “based at least in part on” rather than “based solely on.” Unless explicitly stated otherwise or necessitated by context, the term “or” should be understood to be inclusive. For example, “A or B” could refer to A alone, B alone, or both A and B.

What is claimed is:

1. A method, comprising:
generating a model to predict an amount of time to perform one or more first tasks; and
predicting, using the model, the time to perform the one or more first tasks based, at least in in part, on information indicating progress of the one or more first tasks and information indicating progress of one or more second tasks.

2. The method of claim 1, wherein the one or more first tasks comprise a construction project.

3. The method of claim 1, wherein the model is generated such that an effect on the prediction of the information indication progress of the one or more first tasks is substantially proportional to a difference between the information indicating progress of the one or more first tasks and the information indicating progress of the one or more second tasks.

4. The method of claim 1, wherein the information indicating progress of the one or more first tasks comprises one or more values determined based, at least in part, on one or more values indicating a progress of the task compared to an elapsed time corresponding to the one or more first tasks.

5. The method of claim 1, wherein:
the method further comprises assigning one or more temporal checkpoints to the task; and
the information indicating progress of the one or more first tasks comprises one or more values determined based, at least in part, on one or more values indicating a progress of the task following a previous checkpoint.

6. The method of claim 1, wherein:
the method further comprises assigning two or more temporal checkpoints to the task; and
the information indicating progress of the one or more first tasks comprises one or more values determined based, at least in part, on one or more values indicating a progress of the task following a first previous checkpoint and one or more values indicating a progress of the task following a second previous checkpoint.

7. The method of claim 1, wherein:
the information indicating progress of the one or more first tasks comprises at least two values; and
the method further comprises using a neural network to generate weightings respectively corresponding to the at least two values.

8. An apparatus comprising processing circuitry to:
generate a model to predict an amount of time to perform one or more first tasks; and
predict, using the model, the time to perform the one or more first tasks based, at least in in part, on information indicating progress of the one or more first tasks and information indicating progress of one or more second tasks.

9. The apparatus of claim 8, wherein the one or more first tasks comprise a construction project.

10. The apparatus of claim 8, wherein the model is generated such that an effect on the prediction of the information indication progress of the one or more first tasks is substantially proportional to a difference between the information indicating progress of the one or more first tasks and the information indicating progress of the one or more second tasks.

11. The apparatus of claim 8, wherein the information indicating progress of the one or more first tasks comprises one or more values determined based, at least in part, on one or more values indicating a progress of the task compared to an elapsed time corresponding to the one or more first tasks.

12. The apparatus of claim 8, wherein:
the processing circuitry is further to assign one or more temporal checkpoints to the task; and
the information indicating progress of the one or more first tasks comprises one or more values determined based, at least in part, on one or more values indicating a progress of the task following a previous checkpoint.

13. The apparatus of claim 8, wherein:
the processing circuitry is further to assign two or more temporal checkpoints to the task; and
the information indicating progress of the one or more first tasks comprises one or more values determined based, at least in part, on one or more values indicating a progress of the task following a first previous checkpoint and one or more values indicating a progress of the task following a second previous checkpoint.

14. The apparatus of claim 8, wherein:
the information indicating progress of the one or more first tasks comprises at least two values; and
the processing circuitry is further to use a neural network to generate weightings respectively corresponding to the at least two values.

15. A non-transitory computer-readable medium storing instructions that, when performed by one or more processors, cause the one or more processors to at least:
generate a model to predict an amount of time to perform one or more first tasks; and
predict, using the model, the time to perform the one or more first tasks based, at least in in part, on information indicating progress of the one or more first tasks and information indicating progress of one or more second tasks.

16. The non-transitory computer readable medium of claim 15, wherein the model is generated such that an effect on the prediction of the information indication progress of the one or more first tasks is substantially proportional to a difference between the information indicating progress of the one or more first tasks and the information indicating progress of the one or more second tasks.

17. The non-transitory computer readable medium of claim 15, wherein the information indicating progress of the one or more first tasks comprises one or more values determined based, at least in part, on one or more values indicating a progress of the task compared to an elapsed time corresponding to the one or more first tasks.

18. The non-transitory computer readable medium of claim 15, wherein:
the instructions are to cause the one or more processors further to assign one or more temporal checkpoints to the task; and
the information indicating progress of the one or more first tasks comprises one or more values determined based, at least in part, on one or more values indicating a progress of the task following a previous checkpoint.

19. The non-transitory computer readable medium of claim 15, wherein:
the instructions are to cause the one or more processors further to assign two or more temporal checkpoints to the task; and
the information indicating progress of the one or more first tasks comprises one or more values determined based, at least in part, on one or more values indicating a progress of the task following a first previous checkpoint and one or more values indicating a progress of the task following a second previous checkpoint.

20. The non-transitory computer readable medium of claim 15, wherein:
the information indicating progress of the one or more first tasks comprises at least two values; and
the instructions are to cause the one or more processors to further use a neural network to generate weightings respectively corresponding to the at least two values.
